(19) United States
(12) Patent Application Publication
(10) Pub. No.: US 2025/0115168 A1
(43) Pub. Date: Apr. 10, 2025

(54) CONTROL SYSTEMS PROVIDING ROUTE SEGMENT SPECIFIC DRIVE MODES TO ENHANCE ELECTRIC VEHICLE OPERATION AND DURABILITY

(71) Applicant: Hydrogen Vehicle Systems Ltd, Glasgow (GB)

(72) Inventor: David Telford, Glasgow (GB)

(21) Appl. No.: 18/491,410

(22) Filed: Oct. 20, 2023

(30) Foreign Application Priority Data
Oct. 5, 2023 (GB) 2315291.1

(51) Int. Cl. B60L 58/40; B60L 1/00; B60L 7/10; B60L 15/20; B60L 50/75; G06F 30/15

(52) U.S. Cl. CPC B60L 58/40; B60L 15/20; B60L 50/75; G06F 30/15; B60L 1/003; B60L 7/10; B60L 15/2045; B60L 2210/10; B60L 2210/40; B60L 2240/545; B60L 2240/547; B60L 2240/622; B60L 2240/642; B60L 2240/68; B60L 2260/20; B60L 2260/46; B60L 2260/50

(57) ABSTRACT

There is provided a control system for an electric vehicle comprising a power train, the control system comprising: a first controller configured to automatically select a drive mode for the vehicle based on a whole vehicle operation model; and a second controller coupled to the first controller, the second controller configured to adjust a set of tuning parameters for the vehicle, whereby the second controller is configured to receive a signal from the first controller to adjust the set of tuning parameters such that the vehicle operates in the selected drive mode. Thus enhancing the operation and durability characteristics of the vehicle.

### TECHNICAL FIELD

The present disclosure relates to a control strategy for an electric vehicle, wherein two controllers are employed; controller one is deployed to model the segmented route map of the journey, while controller two implements route segment specific drive modes to enhance the operation and durability characteristics of the vehicle.

### BACKGROUND

It is known that vehicle power trains of all types can offer the driver of the vehicle a selection of drive modes, such as “ECO”, “Normal”, and “Performance”. Electric vehicles may have a controller setting or a driver-controlled setting that sets the target state of charge of the battery system. The drive modes represent a set of adjustable parameters, for example the maximum power, the peak torque deliverable, or the rate of acceleration. Such parameters are controlled to provide the given drive mode. In some cases, the parameters may be set by external conditions such as anti-lock braking systems that set traction control, or environmental temperature that sets the allowable power that can be safely drawn from the battery system. One of the disadvantages of mode selection by driver is that the driver may simply select a single mode for the entire journey. Such a scenario would be disadvantageous to the overall performance and fuel efficiency of the vehicle. In general, the limitations of existing driver modes are somewhat crude and not representative of the complexity and related opportunities for overall energy efficiency in an average journey for an electric vehicle, most especially a commercial electric vehicle.

In some cases, external factors can be used to automatically set a drive mode. However, these cases are restricted to a specific function. For example, setting the traction control and related anti-skid characteristics of the vehicle operation when the temperature falls below a certain level and there is a risk of ice formation on the road surface.

It is an object of the disclosure to address one or more of the above-mentioned limitations.

### SUMMARY

According to a first aspect of the disclosure, there is provided a control system for an electric vehicle comprising a powertrain, the control system comprising: a first controller configured to automatically select a drive mode for the vehicle based on a whole vehicle operation model; and a second controller coupled to the first controller, the second controller configured to adjust a set of tuning parameters for the vehicle; whereby the second controller is configured to receive a signal from the first controller to adjust the set of tuning parameters such that the vehicle operates in the selected drive mode. The control strategies of this disclosure are employed to achieve, amongst other attributes, enhanced performance and durability for electric vehicles.

Optionally, the first controller comprises a simulation module configured to provide the whole vehicle route model, the simulation module automatically selecting the drive mode for the vehicle.

Optionally, the simulation module is configured to model one or more of the following in the generation of the whole vehicle model: thermal management of the powertrain; one or more hydrogen powered fuel cells with controlling balance-of-plant components; an energy storage system (ESS) comprising a battery, fuel cell and ESS thermal management; ESS state of charge data as it relates to optimized energy capture from regenerative braking; a high voltage DC/DC convertor; a HVAC subsystem; a power distribution subsystem; the second controller; a high voltage battery; an E-drive subsystem; a DC/AC inverter; an e-acle; a hydrogen fuel subsystem; one or more hydrogen tanks; a hydrogen supply and safety monitoring system; hydrogen capacity and refuelling capabilities; a parasitic loads management subsystem; a cabin environmental control subsystem; a cargo environmental and on-loading and off-loading control subsystem; an e-stop; a low voltage battery; and an axle-wheel-tyre subsystem.

Optionally, the simulation module is configured to provide AI-enabled predictive control.

Optionally, the first controller comprises one or more interfaces configured to receive a plurality of inputs, the whole vehicle model being dependent on these inputs.

Optionally, at least one of the one or more interfaces is a wire communications interface.

Optionally, the plurality of inputs comprises one or more types of input data from: a driver of the vehicle; route data; traffic data; environmental data; traffic management data; Global Positioning System data; terrain data; powertrain subsystem thermal management data; status of ES component data; parasitic load data; power flows in one or more subsystems of the vehicle data; DC/DC convertors and two way DC/AC inverter data for one or more power axles of the vehicle; vehicle speed and driver demand for change in speed data; acceleration and deceleration related to up- and down-gradients in journey terrain data; current hydrogen inventory data; ESS state of charge data; ESS state of charge data as it relates to optimized energy capture from regenerative braking; power demand ramp rate on fuel cell data or related water management data.

Optionally, the AI-predictive control is configured to utilise remaining route data analysis to achieve specific drive mode operations that optimize fuel efficiency.

Optionally, the AI-predictive control is configured to optimize energy management of the vehicle based on route segmentation analysis for a given journey.

Optionally, the AI-predictive control is adapted to configure the ESS state-of-charge to provide optimum energy availability to support up-gradient acceleration of the vehicle, and down-grade energy recapture from regenerative braking.

Optionally, the second controller comprises a vehicle control unit.

Optionally, the vehicle control unit is configured to control the powertrain of the vehicle.

Optionally, the vehicle control unit comprises at least one or more interfaces configured to adjust the set of tuning parameters.

Optionally, the set of tuning parameters comprises at least one or more of: a fuel cell peak power limit, a fuel cell Power up slew rate, a fuel cell power down slew rate, an ESS max State of Charge (SOC), an ESS Min SOC, a target SOC at time t, a fuel cell array target power.

Optionally, the set of tuning parameters are optimized using AI algorithms to achieve enhanced performance and durability of the vehicle power train subsystems.

Optionally, the second controller functionality is replaced in its entirety by the first controller.

Optionally, the selected drive mode is one of a plurality of operating modes comprising a performance mode, a balanced mode, a life extension mode, a fuel efficiency mode, a dynamic range adjust mode, a range extend mode, and a driver assist mode.

According to a second aspect of the disclosure, there is provided a method of automatically selecting and setting a drive mode for one or more/a plurality of segments of a route for an electric vehicle using the control system according to the first aspect.

Optionally, the electric vehicle comprises the control system of any preceding claim.

Optionally, the electric vehicle further comprises a plurality of energy sources and an energy storage means, wherein the plurality of energy sources comprises a one or more fuel cell subsystem.

Optionally, the plurality of energy sources comprises an energy storage system comprising a battery.

Optionally, the fuel cell subsystem comprises a hydrogen fuel cell.

Optionally, the fuel cell subsystem comprises an alternative electrochemical technology.

Optionally, the fuel cell subsystem comprises a proton exchange membrane fuel cell.

Optionally, the energy storage system is a battery.

Optionally, the energy storage system comprises a battery and a supercapacitor.

### DESCRIPTION OF THE DRAWINGS

The disclosure is described in further detail below by way of example and with reference to the accompanying drawings, in which:

FIG. 1A is a diagram showing an example embodiment of a control system for an electric vehicle;

FIG. 1B is a diagram showing the software structure for controller one of the control systems of FIG. 1A;

FIG. 2 is a diagram of the modelling suite for controller one in the system of FIG. 1A;

FIG. 3 is a diagram showing the data needed for the predictive drive suite for controller one;

FIG. 4 is a diagram showing the software modules of controller one and how they interact;

FIG. 5 is a flow chart showing the use of state estimators in controller one;

FIG. 6A is an example of a terrain map that can be used as an input for the remaining route software module of controller one;

FIG. 6B is a set of figures showing the analysis of the map data from FIG. 6A;

FIG. 7A is an example of an altitude map that can be derived from the terrain map;

FIG. 7B is a section of the altitude map of FIG. 7A:

FIG. 7C is the section of altitude map of FIG. 7B after the peak searching algorithm has been applied;

FIG. 7D is a route level segmentation of the altitude map of FIG. 7B;

FIG. 8 is a graphical schematic of the processes undertaken by the current segment module of FIG. 4;

FIG. 9A is a table showing an example set of tuning parameters that can be used as an input for controller one;

FIG. 9B is a graphical representation of the fuel cell array leader-follower configuration during vehicle start-up;

FIG. 9C is a graphical representation of the fuel cell array leader-follower configuration during normal vehicle operation;

FIG. 9D is a diagram of the forward-looking rolling average power;

FIG. 9E is a graphical representation of the fuel cell power output when the maximum output of each fuel cell is lower than the rolling average power;

FIG. 9F is a graphical representation of the fuel cell power output when the vehicle is in an ECO-type mode;

FIG. 9G is a graphical representation of the fuel cell, battery and regenerative braking power output;

FIG. 9H is the power demand of the fuel cells during start-stop operation of the vehicle;

FIG. 9I is the power demand of the fuel cells during normal operation at motorway speeds for the vehicle;

FIGS. 9J and 9K shows the energy storage system state for a drive cycle of the vehicle on the motorway;

FIG. 10A is a graphical comparison of the operation for the control system of the present disclosure against a dumb controller for a journey for a vehicle;

FIG. 10B is a graphical comparison of the operation for the control system of the present disclosure against a dumb controller during a peak demand section of the journey of FIG. 10A;

FIG. 10C is a graphical comparison of the operation for the control system of the present disclosure against a dumb controller during a trough demand section of the journey of FIG. 10A; and

FIG. 11 is an example embodiment of an electric vehicle in which the control system of the present disclosure is deployed.

### DESCRIPTION

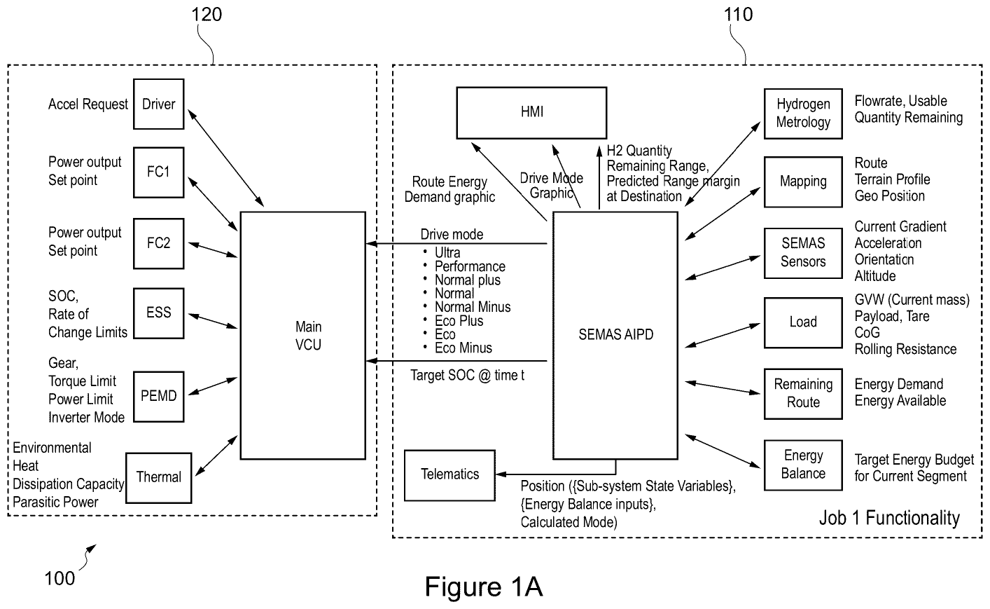

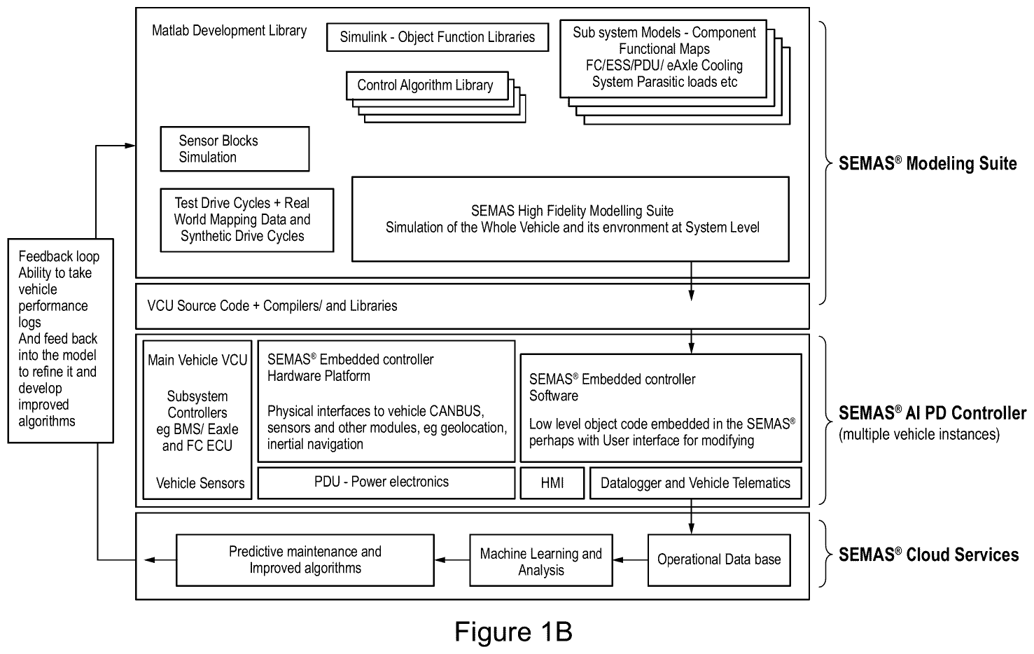

FIG. 1 is a diagram showing an example embodiment of a control system 100 for an electric vehicle. The control system is comprised of two controllers: controller one 110 and controller two 120. The controllers are coupled such that controller two receives a signal from controller one. Controller one 110 in this embodiment is a System Energy Management using Adaptive Simulation (SEMAS®) controller whilst controller two 120 is a vehicle control unit (VCU).

The SEMAS® controller 110 is in charge of the macro control functions for the electric vehicle along its journey. The SEMAS® controller will also receive external information—such as proposed route, terrain maps, traffic updates and other factors—as well as the current state of the vehicle (such as the mass of the cargo in a commercial vehicle application, the amount of fuel available, etc.) to produce a predictive model of the vehicle journey and derive the predicted energy requirements along its journey, subject to the external and internal information flows. This model will show the predicted energy profile of the route which is analysed by the SEMAS® controller 110 to automatically select the best drive mode for the vehicle for each segment of the route. As the vehicle then moves along its journey, the SEMAS® controller 110 sends periodic signals to the VCU 120. The VCU 120 embodies the drive modes for the electric vehicle and is responsible for updating the operational mode of all the vehicle subsystems depending on the drive mode selected. When the VCU 120 receives the signal from the SEMAS® controller 110, the VCU updates the relevant internal variables of the vehicle subsystems. The variables that are updated by the VCU includes, but are not limited to: motor torque, motor peak power, battery charge rates, battery minimum state-of-charge, battery maximum state-of-charge, battery power, hard and soft limits on the power demand ramp rates for the battery and the fuel cell.

Therefore, in this embodiment of the invention, the SEMAS® controller 110 works as an advisory controller to the VCU 120 to automatically set and update the drive mode. This system control strategy allows for an improved dynamic performance of the electric vehicle. The SEMAS® controller 110 itself is comprised of a number of suites and modules to provide the predicted operational strategy for the vehicle during its journey.

FIG. 1B shows the software structure for the SEMAS® controller 110 of FIG. 1A. The software structure comprises three main elements: the modelling suite, the artificial intelligence predictive drive (AIPD) and the cloud services. The modelling suite serves as a high-fidelity digital twin of the whole vehicle and comprises a computer aided system with sub-system physics-based models and abstraction layers. The AIPD provides high level on-board vehicle systems control which utilizes a-priori route and load information as well as data collected from on-board sensors. Finally, the cloud services allow for data connectivity and fleet management services. Fleet management services include, but are not limited to, compliance, security, planned preventative maintenance, over-the-air (OTA) breakdown support and warranty validation.

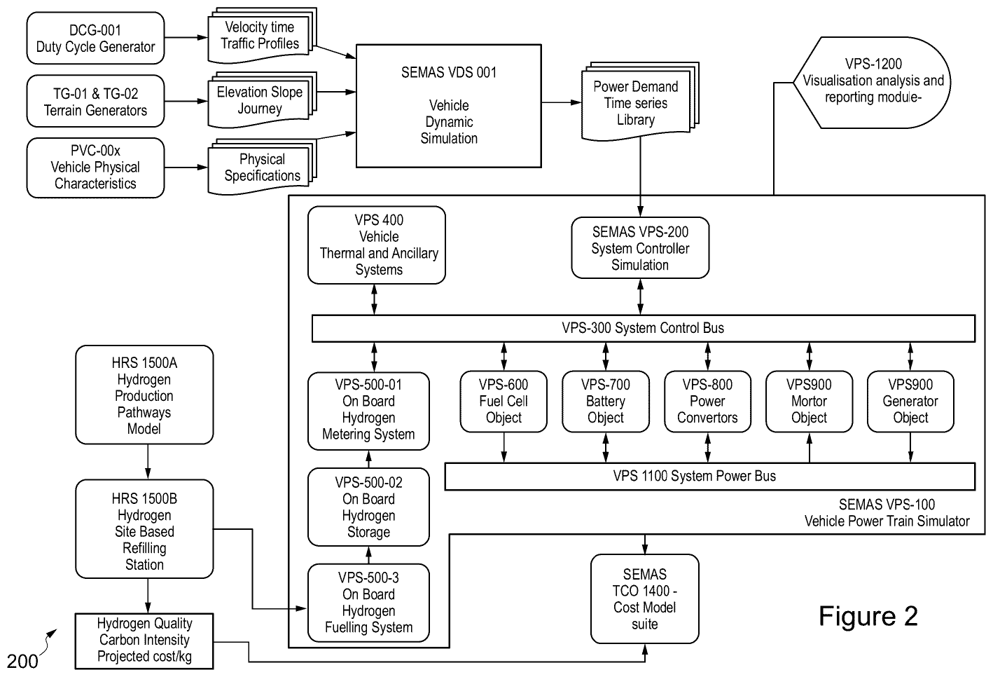

FIG. 2 shows the modelling suite 200 of the SEMAS® controller 110. The modelling suite 200 is composed of a set of software tools to develop, test and maintain a high-fidelity dynamic model of the electric vehicle and its control system. It includes a whole-vehicle simulation model implemented, for example, in Simulink which includes software modules representing (at high fidelity) accurate physics-based models of each of the vehicle subsystems. The suite 200 also includes a set of tools to run the model through standard drive cycles and data sets such as those representing real world terrain, end user drive cycles, cargo management requirements, fleet management and driver safety/comfort profiles. The suite 200 aims to provide accurate geolocated datasets (including the vehicle subsystems performance records at high spatial frequency for previous journeys) and contains software tools to generate both synthetic terrains and real-world terrains, representative of, for example, commercial vehicles, together with a suite of standard idealised drive cycles, to generate standardised performance data for any of the modular power train vehicle configurations.

The modelling suite provides a testing ground for a simulated model of the vehicle, at a detailed subsystem level, across the entire journey. It also provides the source code for the artificial intelligence predictive drive (AIPD) suite to ensure compatibility between the two.

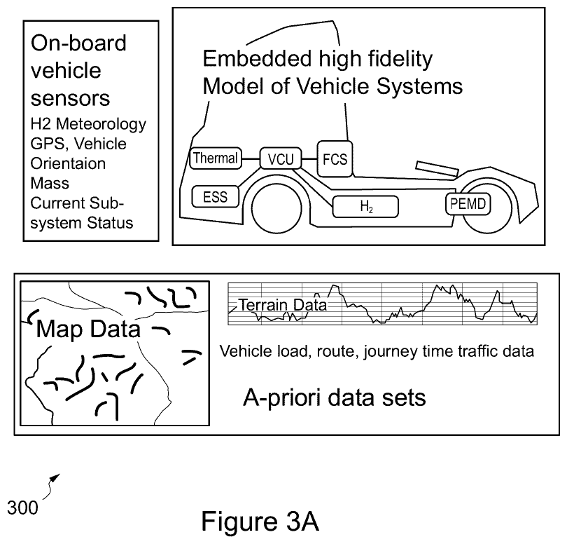

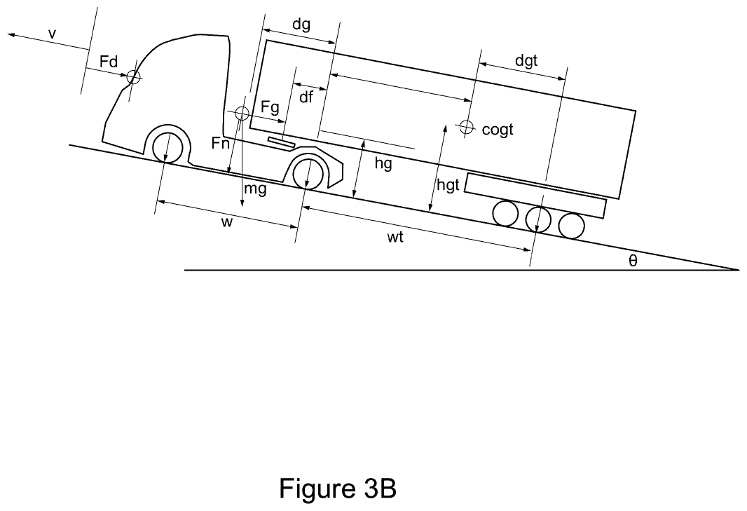

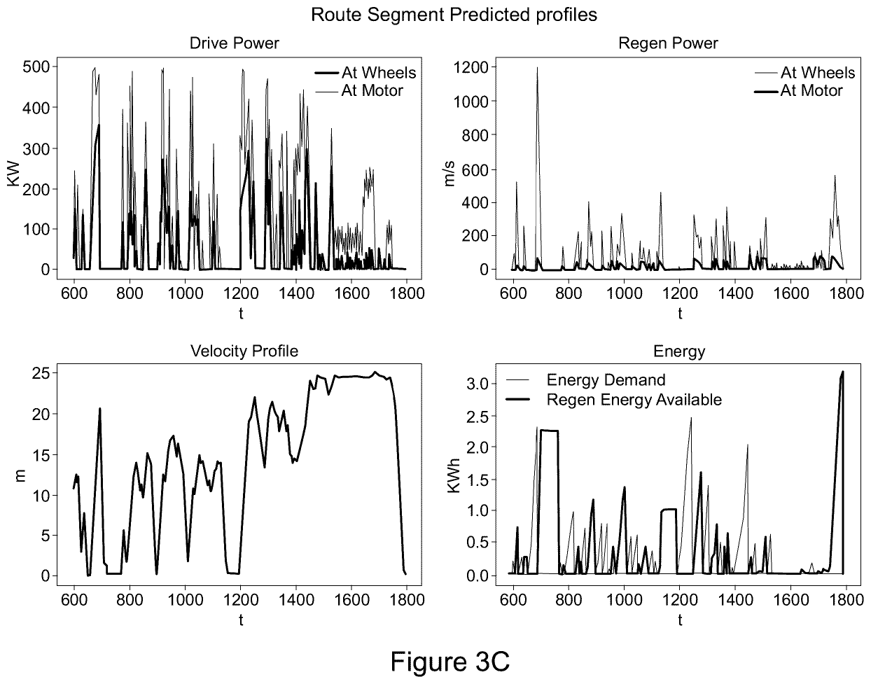

FIG. 3 shows the data sets 300 used by the AI predictive drive (AIPD) suite of the SEMAS® controller 110. The AIPD suite is a high-level supervisory intelligent controller that monitors, amongst other parameters, the vehicle's current state.

A-priori route data and on-board sensors as inputs to the embedded vehicle simulation which is used to predict the energy demand profile for the vehicle's route. Further, a set of ‘least-cost’ algorithms are used to derive the optimised settings for tuneable parameters of the subsystems of the power train that then define the drive mode of the current route segment and set the target configuration for the next route segment.

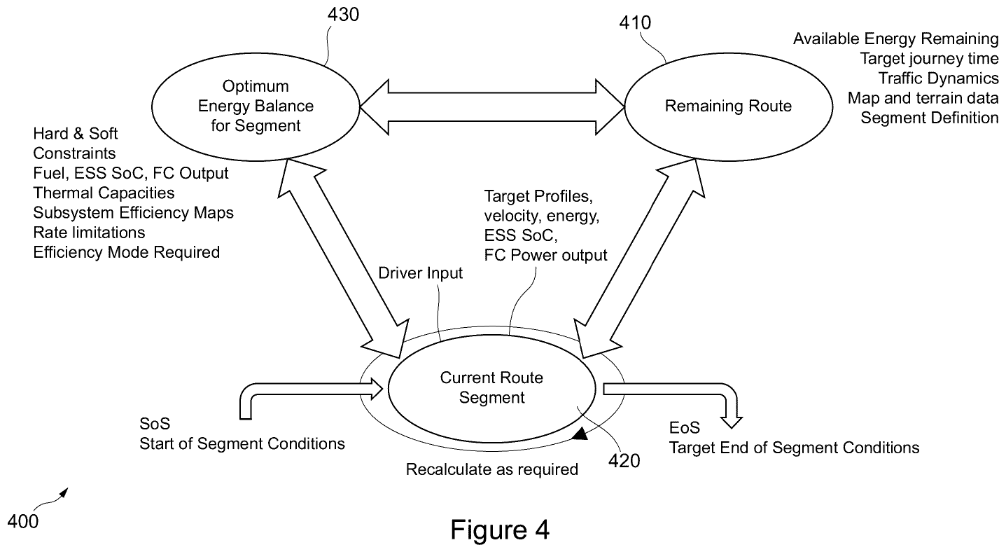

FIG. 4 shows the different software modules 400 that form part of the SEMAS® controller 110. These include: a remaining route module (RR) 410, a current route segment module 420 and the optimum energy balance for segment module 430. The three modules are interconnected. Each software module executes their own tasks.

Before the journey, the RR module 410 receives the planned route data, and uses the a-priori data sets, to undertake a detailed simulation that takes account of the vehicle cargo payload and fuel requirement based on the defined drive profile and terrain map. The RR module 410 uses these data to determine such parameters as: the segmentation strategy, the energy demand for the route, the drive mode and set points for each segment and the energy budget for each route segment including the appropriate available operating margins. Route segmentation strategy for a given journey is not a trivial task, the number and length of the segments will depend, amongst other factors, on the number and precision of the target drive modes and identification of peak power demand, peak to average power ratios and energy demand to complete that segment. For example, if there is no need to switch drive modes from an energy balancing or power demand perspective then segments will be longer. Conversely, where the predicted energy demand or significant regenerative braking opportunity (energy capture via the on-board ESS for a sustained down gradient, for example) which requires a specific state-of-charge for the ESS at the start or end of the segment then that will determine the ideal segment length. A key variable set for a commercial electric vehicle is dependent on the “cargo profile”. This cargo profile includes, but is not limited to weight, type, delivery and pick-up schedules, environmental requirements (cargo cooling, etc.). These factors provide a significant contribution to the calculated energy profile of the route on a whole vehicle analysis basis. The variation in parameters such as cargo type, variable payloads, and other vehicle energy demands represent constitute specific challenges for the efficient operation of electric commercial vehicles. The remaining route energy demand is also a strong function of the target velocity profile and the vehicle mass. By assessing uncertainties and errors, the RR module 410 will advise if the route can be achieved with the current fuel inventory at an acceptable margin. It may also suggest options such as an alternative route, alternative target velocity profile and/or an intermediate refuelling stop as an option to achieve the journey objectives. From the whole route simulation, the RR module 410 will be an important determinant of the segmentation strategy.

The terrain map used by the RR module 410 may be generated using several data sources. In one example, it can be generated from latitude and longitude waypoints tagged with altitude and gradient data from a topology map. In another example, it can be generated based on previous routes the vehicle has undertaken. On the previous routes, the gradient and distance data can be recorded and tagged with the GPS position co-ordinates together with relevant state information (such as load, velocity, and environmental temperature). This route data set can be stored in the cloud at the route segment level and then be available as a-prior data for the RR module 410 to construct the route energy balance taking into account differences in the “library” route and planned route model parameters.

The RR module 410 will identify key set points and split the route (at relatively low spatial resolution) into drive segments. These act as reference way points for predicting rate of fuel consumption and target energy demand. The spatial frequency required for segmentation is determined to a large extent by the available energy stored in the ESS compared to the excess energy required over that provided by the FC subsystem to complete a given segment of the route. This excess energy may be positive or negative and will also depend on the target set point for the succeeding segment. For example, if for a given route segment there is a long-sustained climb then the state-of-charge target for the start of that segment will require that the ESS is close to maximum capacity. For the preceding segment, its length will be strongly influenced by the need to increase the FC subsystem power output above the energy demand required for the sustained climb segment to achieve the target SOC of the ESS at the segment end point.

The set-point target parameters will then be transferred to the current segment (CS) module 420. At the end of each segment the RR module 410 will re-run the simulation on the remaining route, taking into account the fuel consumption and the balance of fuel available and update the set-point target parameters. Where the fuel margin for the remaining route is too small, and the control system will respond by reducing the maximum available peak power from the FC subsystem during transients to conserve fuel. This information is presented to the driver through the dashboard Human Machine Interface (HMI).

The CS module 420 deals with adaptive energy management over the current route segment. It is based on much shorter time horizons and can react to short transient events, such as acceleration from rest to speed, or anticipating significant up or down gradients on the current route segment. The CS module 420 takes the status prior to the specific event and determines the recommended drive mode and the target state-of-charge of the ESS and fuel inventory, at time “t”, to deliver the target vehicle status at the next setpoint. At the setpoint it reports the status to the RR module 410 which then re-calculates the available margins based on the remaining route segment setpoints.

The energy balance (EB) module 430 can be designed in two embodiments in the whole vehicle model. The first is as a development tool in the whole vehicle simulation analysis. In this embodiment, the EB module 430 evaluates the short-term energy balance requirements. It does this by looking at the energy available and the predicted energy demand for current route segment and then determining the best drive mode settings to dynamically balance supply and demand. The decision-making process is done through multi-variate optimisation by finding the optimum solution over several interconnected variables. These variables include but are not limited to; limits on ramp rates of the FC subsystem, current thermal management requirements, working data points on the efficiency maps of the FC, ESS and the power electronics and electric drive (PMED), and constraints to ensure acceptable driver experience and expectation. These variables are then compiled into one of the drive mode cycle definitions to achieve the best combinations of variables for setting the energy demand profile for a given segment.

The second embodiment of the EB module 430 is where there are libraries of drive modes and from which the CS module 420 chooses the best library drive modes based on whole vehicle simulation evaluations. This embodiment is as FIG. 1, where the CS function is embodied in the VCU 120 as an encoded series of drive mode parameters and the SEMAS® AIPD controller 110 instructs the VCU 120 which one to select. The optimum choice from the simulations is made based on how well that library drive mode achieves a set of objectives. These objectives can include acceptable power train dynamic performance, thermal management requirements, fuel efficiency and durability requirements of the electrochemical components of the power train. If more drive modes are needed or if there is a need to eliminate or merge less effective modes, then the second embodiment of the EB module 430 can be used to test and validate the library of drive modes against the real-world terrain expectations.

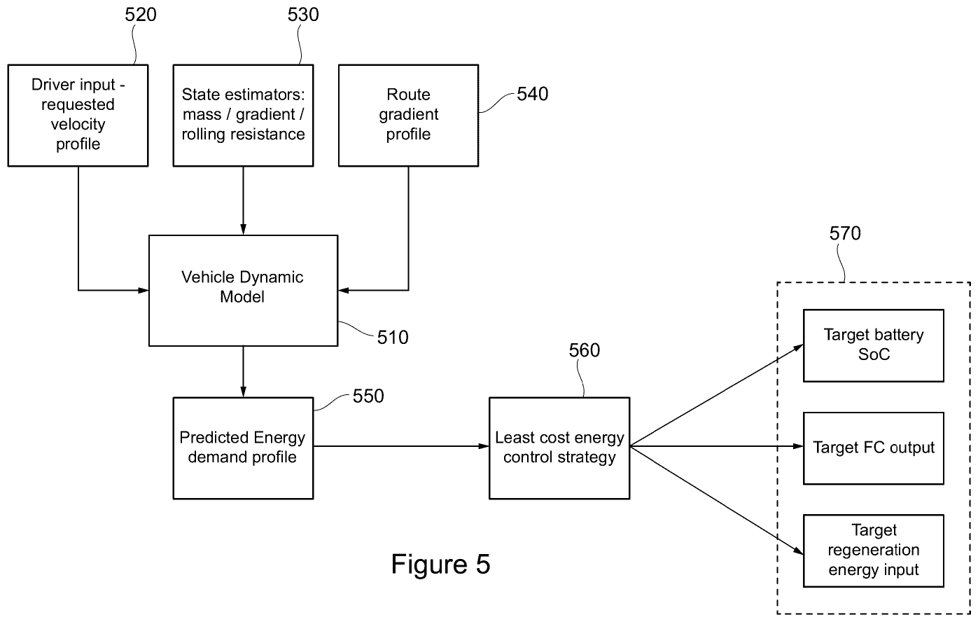

FIG. 5 is a flow chart showing the use of state estimators 530 in the vehicle dynamic model 510 as employed by the SEMAS® AIPD controller 110.

The vehicle dynamic model 510 receives a variety of inputs that can be categorised into three main groupings. The first is the driver inputs 520 which include the requested velocity profile of the vehicle and any braking events. Second, is the state estimators 530, such as the mass of the vehicle, the gradient of the terrain or the rolling resistance of the vehicle. The third group of inputs is the route gradient profile 540. The vehicle dynamic model 510 outputs a predicted energy demand profile 550 for the vehicle along a given route which in turn is used to provide the least cost energy control strategy 560. This control strategy for the vehicle presets a number of targets 570 for internal components of the power train such as the target battery state-of-charge, the target fuel cell power output and the target regeneration energy input.

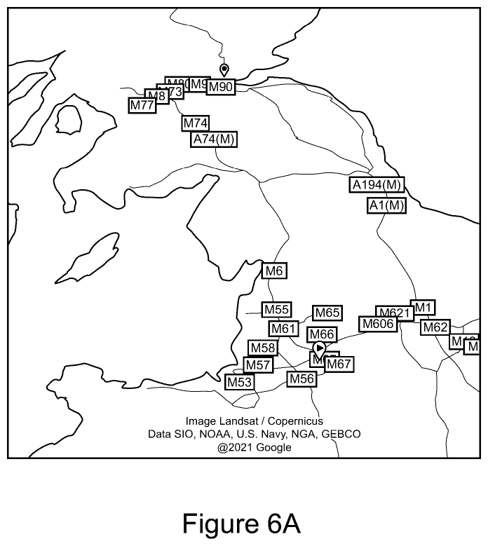

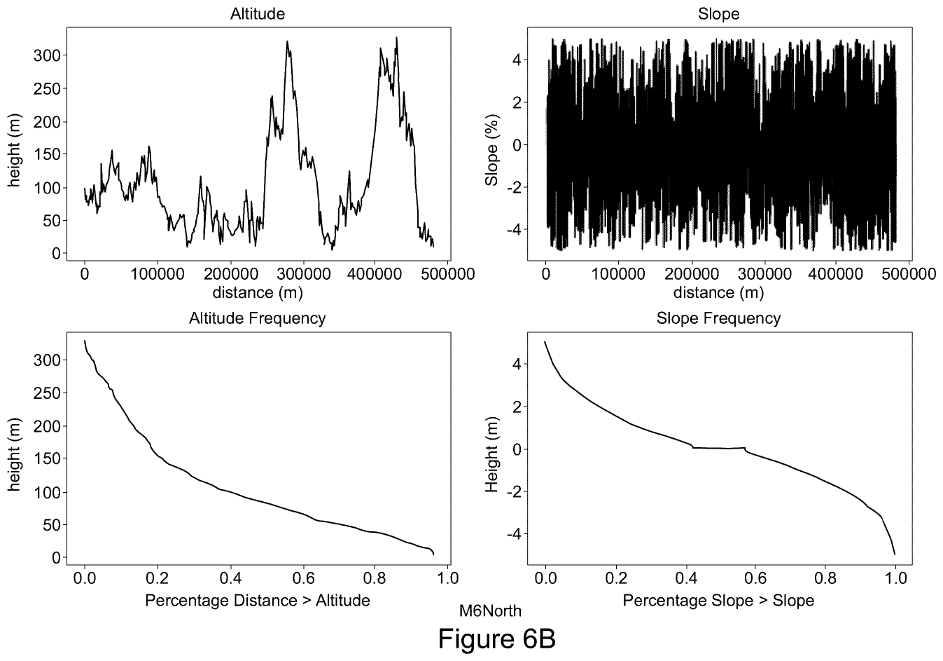

FIG. 6A is an example of a terrain map that can be used as an input for the RR module 410. In this example, the terrain map is showing a route along the M6 north motorway in the United Kingdom. FIG. 6B shows an analysis of the terrain map data for the M6 north motorway. The altitude graph shows peaks at Shap Summit on the M6 and at Beattock Summit on the M74. In the mapping data, the slopes are much larger than experienced by the road as the altitude data exhibits canyon effects due to limited special resolution of the altitude data.

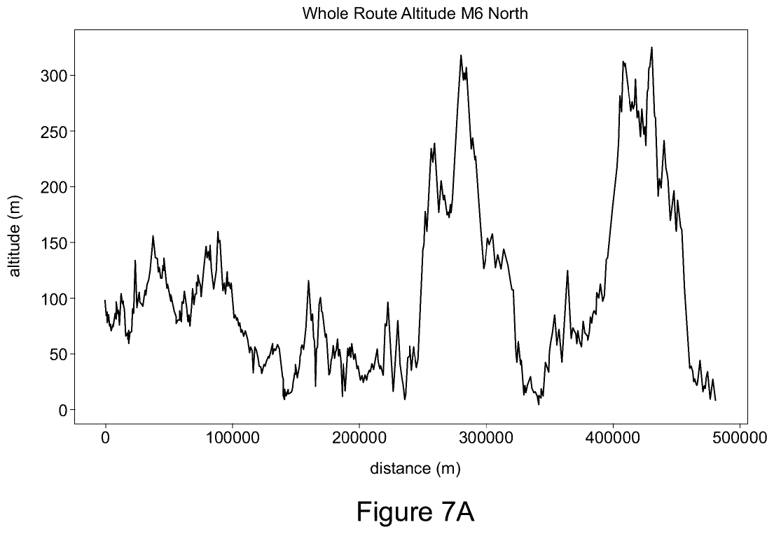

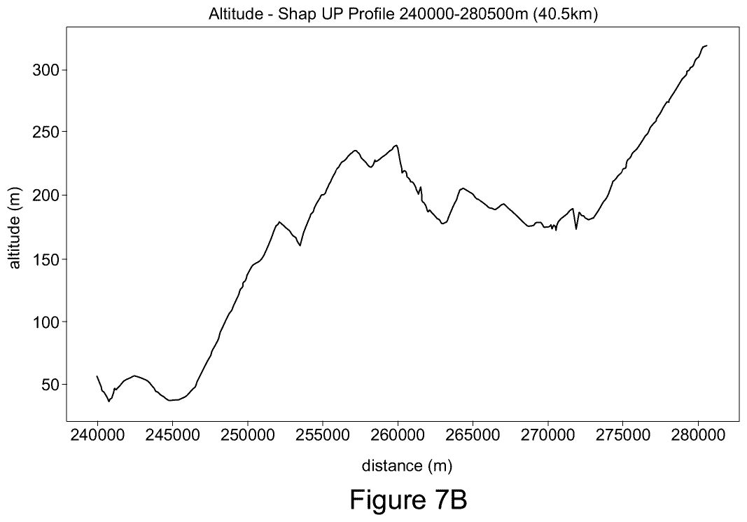

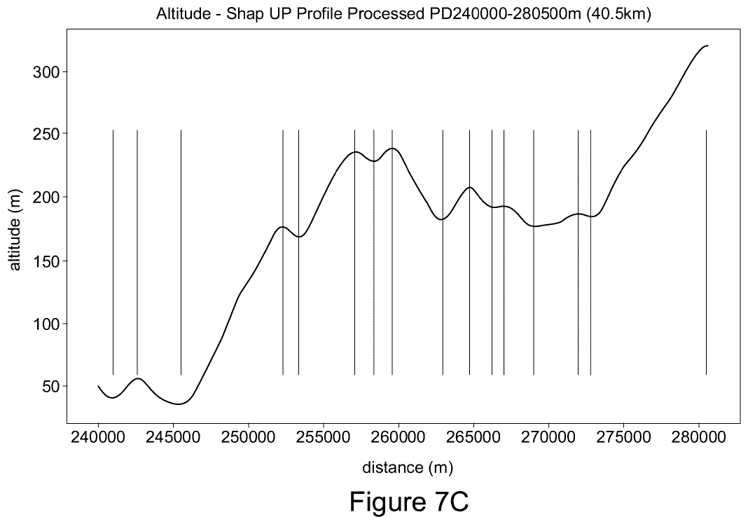

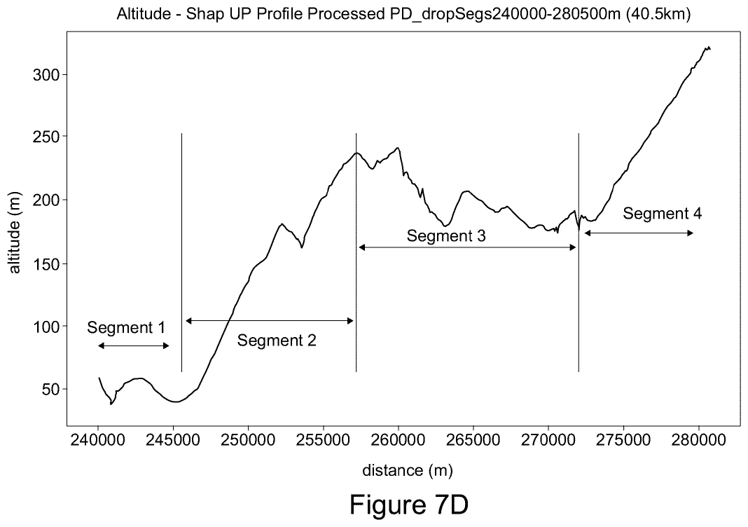

FIG. 7A is an altitude map of the M6 north motorway route shown in FIG. 6A. This altitude data is then processed by the RR module 410. In the embodiment of the present disclosure, the first stage is to process the irregular map waypoints and any geotagged data (including the altitude at route setpoints) to provide a terrain profile at regular intervals. The interval could be, for example, every 5 metres. This terrain profile is then used as the terrain input to the whole vehicle model to calculate the energy demand for the route. This profile is also used for route segmentation. Segmentation processes the route by stripping out the high spatial frequencies, using digital signal processing techniques. In this embodiment of the present disclosure, a Fast Fourier Transform (FFT) low pass filter is used for filtering in the spatial domain, but other digital signal processing (DSP) techniques can also be used. The objective is to identify the change points where the energy demand will be modulated due to gradient or other elements in the route, for example, stop-start, navigating junctions or traffic congestions. The spatial frequency for change point detection will depend on such factors as the size of the energy store and the energy demand for the segment.

FIG. 7B is a section of the altitude map of FIG. 7A. The section shown is a high energy section showing the climb of a vehicle up the Shap Summit. In this figure, the horizontal scale is pulled out and the terrain profile is stretched. FIG. 7C is the section of altitude map of FIG. 7B after the data has been processed through the peak searching algorithm which is a function of controller one 110 in FIG. 1.

FIG. 7D shows the same section of altitude map as shown in FIG. 7B after the map has been split into route segments through the processes applied by the RR module 410 of FIG. 4. Similar energy profiles are collected, and smaller segments are combined. The RR module 410 then splits the route into segments based on grouping the occurrence of similar energy segments. For motorway sections, as shown in FIG. 7D, the route segmentation is based on the predicted speed and the terrain of the route as represented in 1-Dimension. Small gradient fluctuations are ignored.

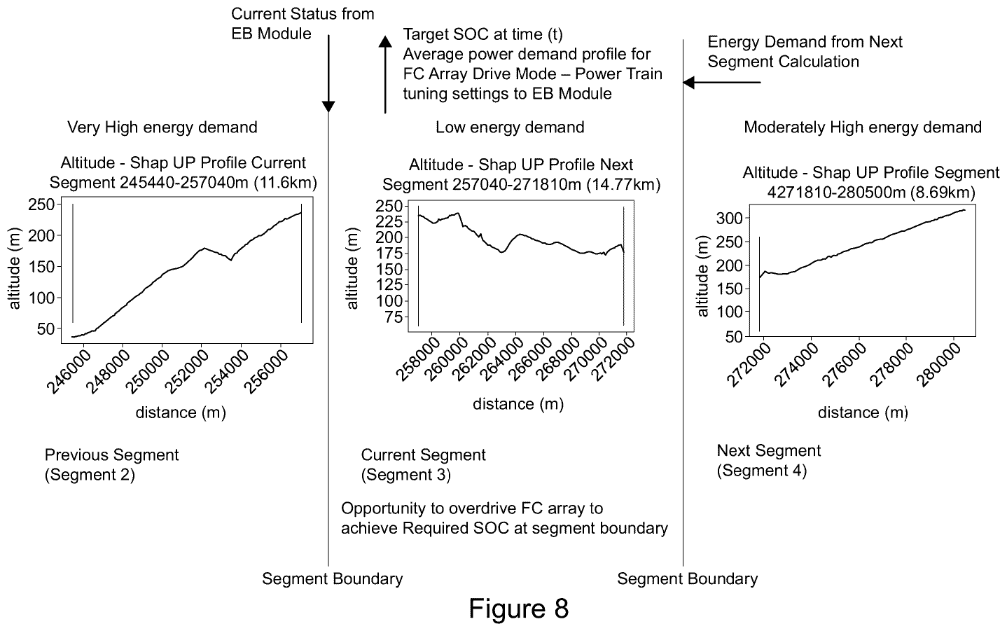

FIG. 8 is a graphical schematic of the segments that are processed by the CS module 420 of FIG. 4. The data used by the CS module 420 is provided by the RR module 410.

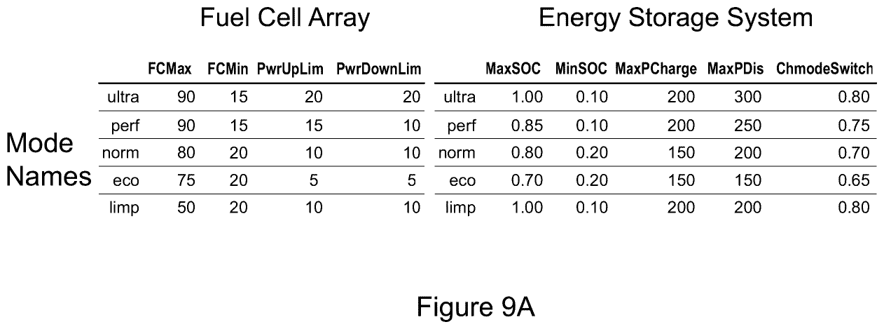

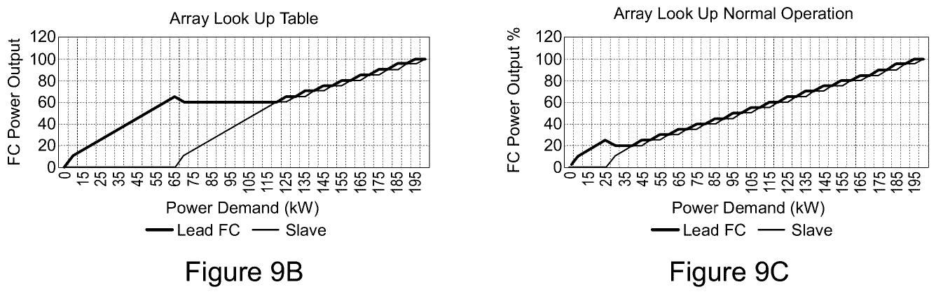

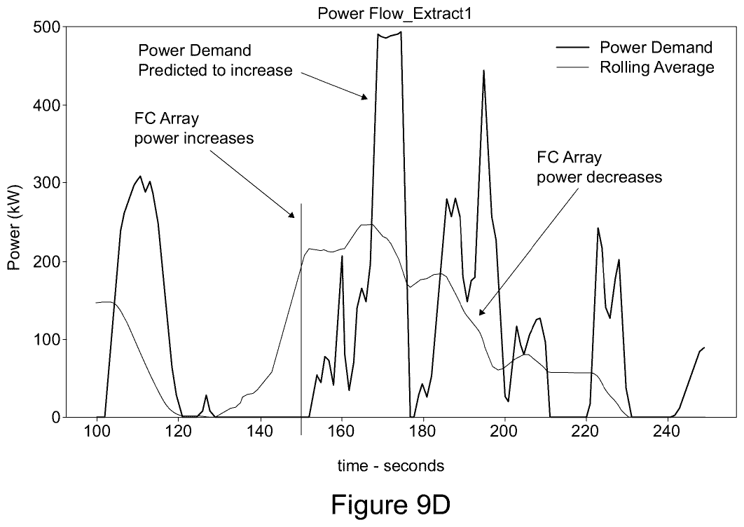

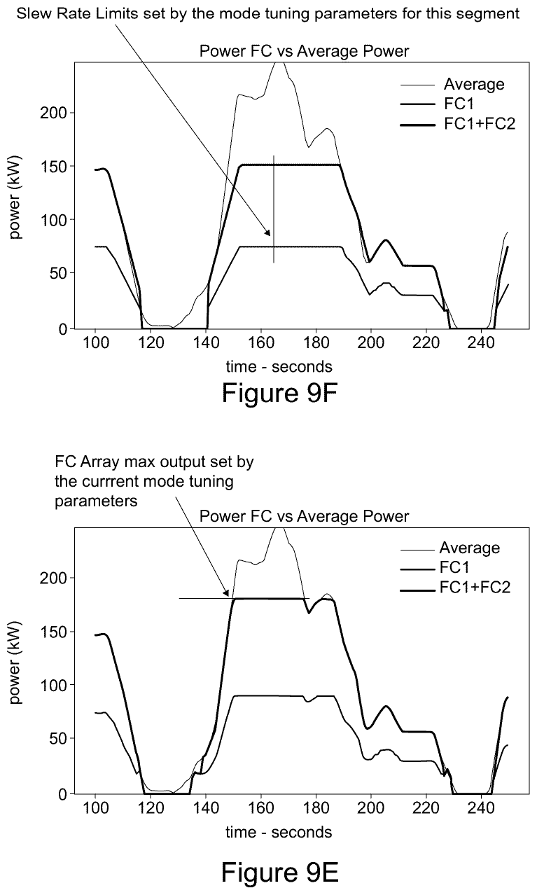

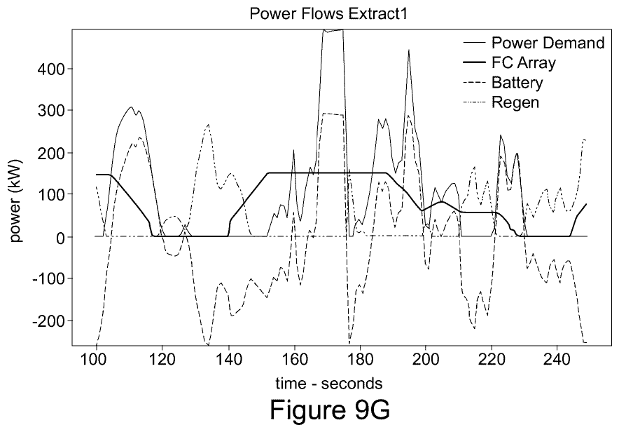

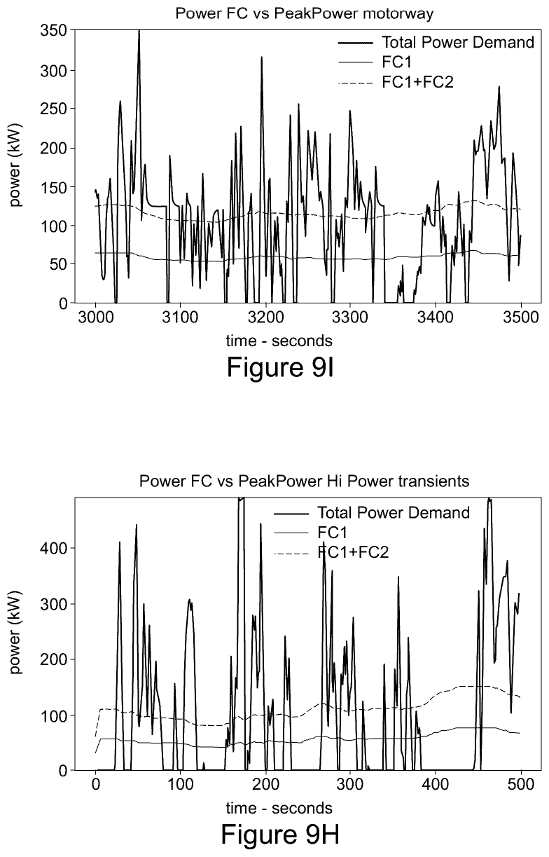

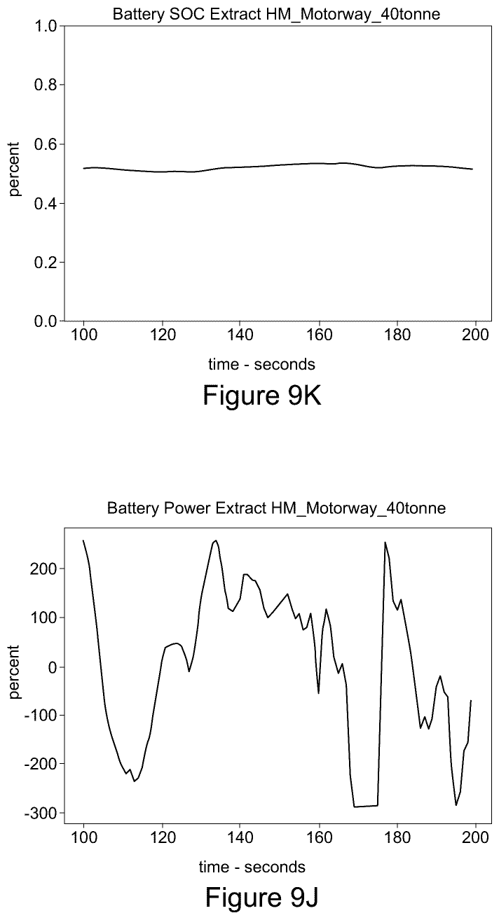

FIG. 9A is a table showing an example set of tuning parameters that can be used by the energy balance module 430 of FIG. 4. The example set shown in FIG. 9A is a simple set of tuning parameters that could be used, in other embodiments more complex and extensive sets of tuning parameters could be used.

The left-hand side table shows the tuning parameters for the fuel cell array. The units for the FC max/FC min power output are in kW and for the power change limits values in kW/sec. The target power and power change limits are complex and depend upon a number of factors including, but not limited to, internal temperatures, environmental temperatures, historical battery SOC and battery temperature.

The right-hand side table shows the tuning parameters for the energy storage system. The max and minimum SOC are expressed as a percentage of max SOC charge and discharge which have units in kW. Chmode is the SOC where the battery management system (BMS) switches from constant current to voltage driven, reducing this value when not required can extend the battery life. As with the FC parameters, this is a minimal data set and in practice additional parameters such as ESS temperatures, cooling availability and other metrics would be included.

FIG. 9B shows the FC array lead/follower configuration for the start-up mode of the vehicle. In start-up mode, the lead fuel cell module is started at low power and the follower fuel cell module is delayed until the power output of the lead reaches 60 kW, for example. For example, for low-speed manoeuvres or for ESS recharge, when stationary the power demand is less than the lead fuel cell so only that fuel cell is in operation.

FIG. 9C shows the FC array lead/follower configuration for the normal operational mode of the vehicle. During normal operation, the lead and follower fuel cell modules mirror each other except at low power output. For example, at low power output, the follower fuel cell module shuts down first leaving the lead fuel cell to handle the low power demands.

FIG. 9D shows the forward-looking rolling average power for a vehicle in operation. The forward-looking rolling average power is calculated by the CS module 420 and the energy demand profile is fed to the energy balance module 430. This allows the EB module 430 to alert the FC array in anticipation of power demand for acceleration events due to gradient, for example. The power demand from the FC array decrease is driven by the desired target SOC of the ESS having been achieved. In FIG. 9D, the rolling average power decreases in advance of the power demand falling, saving primary energy, and by slightly depleting power from the ESS.

FIG. 9E shows the fuel cells power output during the operational case when the maximum output power setting is less than the rolling average power demand. This difference is then made up by the ESS system. FIG. 9F shows the same event for the fuel cells power output when the vehicle is operating in an ECO-type mode. In this drive mode, both the maximum output setting and the power change limits are less than the rolling average power demand, thus conserving primary energy. Conserving primary energy power from the fuel cell array is advantageous in that, amongst other factors, it provides greater fuel efficiency during the vehicle's route.

FIG. 9G is a graph showing the power balance operation to deliver the power demanded by the drive cycle. The fuel cell module response, ESS response and the available power from regenerative braking is shown along with the power demand required. The ESS response is positive when power is being supplied (i.e., the ESS is discharging). The graph illustrates how a smooth response can be achieved during transient power demand scenarios.

FIG. 9H shows the FC array operating at average power for a stop-start segment of a route. The high transient demands are caused by accelerating a vehicle with a full cargo load from rest then stopping again. It is representative of a drive cycle scenario in urban spaces, with short power demand transients up to the peak output limited by the PEMD. At this point, the combined output of the FC array can approximate around 100 kW and is in an ECO-type mode.

FIG. 9I shows the FC array in normal operation at motorway speeds. The FC array output is around 110 kW and maintains the vehicle velocity at full cargo load. The fluctuations above these power demand levels are due to terrain acceleration requirements. At around 33500 seconds, the power demand drops out and there is a larger energy charging event to the ESS.

FIGS. 9J and 9K show a power demand extract from the ESS and of the battery SOC on an example drive cycle. It can be seen that for this example, that the ESS SOC is relatively stable even though the battery power fluctuates. In the example graphs provided, the ESS charge rate is limited to a power maximum of just less than 300 kW and therefore tops out at that point (−300 kW at 170 seconds).

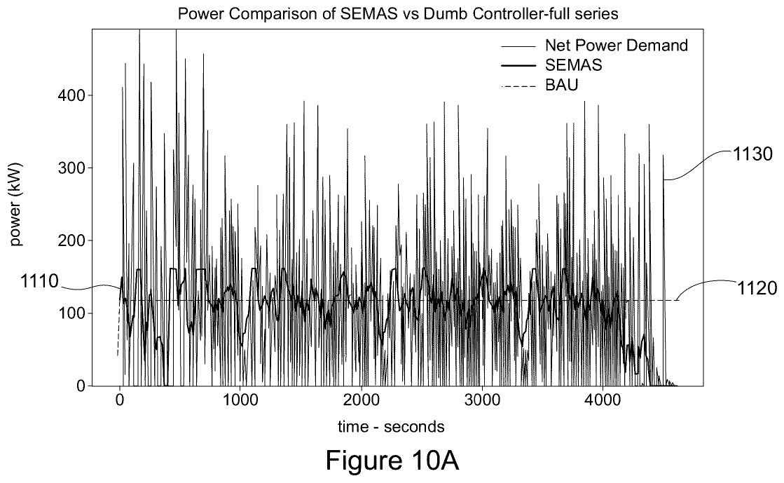

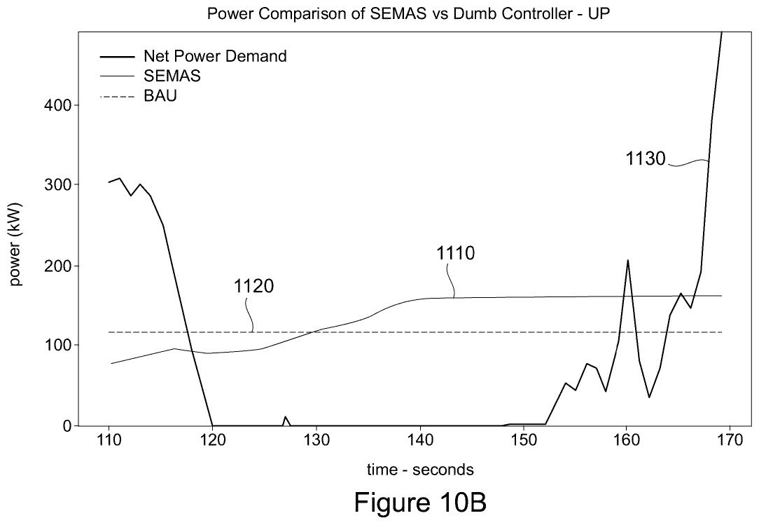

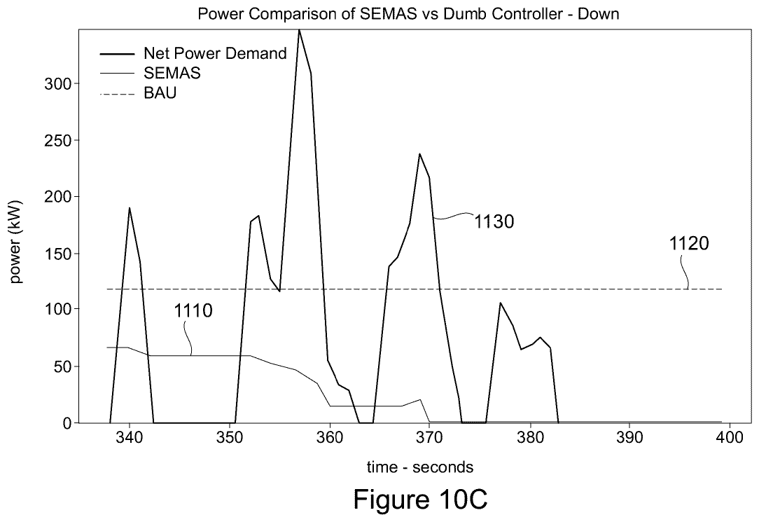

FIG. 10A is a graphical comparison of the power demand for a journey for a vehicle that comprises the control system of the present disclosure 1110 against a vehicle with a dumb controller (BAU) 1120. The net power demand for the journey is also shown 1130. The power output for the dumb controller 1120 is set to the average power consumption which is representative of a “battery SOC maintenance save” algorithm. In other words, the dumb controller acts on the fuel cell to maintain the ESS at a given SOC. Therefore, the dumb controller can only respond to power demand as presented. For the route in FIG. 10A, the fuel consumption achieved by following the SEMAS® derived power demand transients is 15.3% less than what would be achieved by allowing the FC array to follow the average power demand.

FIG. 10B is a graphical comparison of the power demand for the section of the journey of FIG. 10A between 110 and 170 seconds. This section of the journey represents a time where the vehicle net power demand 1130 is increasing. This shows that SEMAS® controller 1110 is gently ramping up the FC array power output to increase the SOC in the ESS prior to the onset of the peak power demand transient. This drive mode function ensures that the ESS can contribute to meet the power demand without stressing the FC array.

FIG. 10C is a graphical comparison of the power demand for the section of the journey in FIG. 10A between 340 and 400 seconds. This section of the journey represents a time where the vehicle net power demand 1130 is decreasing. During this time period, the SEMAS® controlling is cutting the power output from the FC array, and hence fuel consumption, in advance of a down gradient in the vehicle journey. The peak net power demand at 340s, 370s, and 380s are then met by the ESS unit which is depleted to absorb the energy from the regeneration events at 390s and 400s.

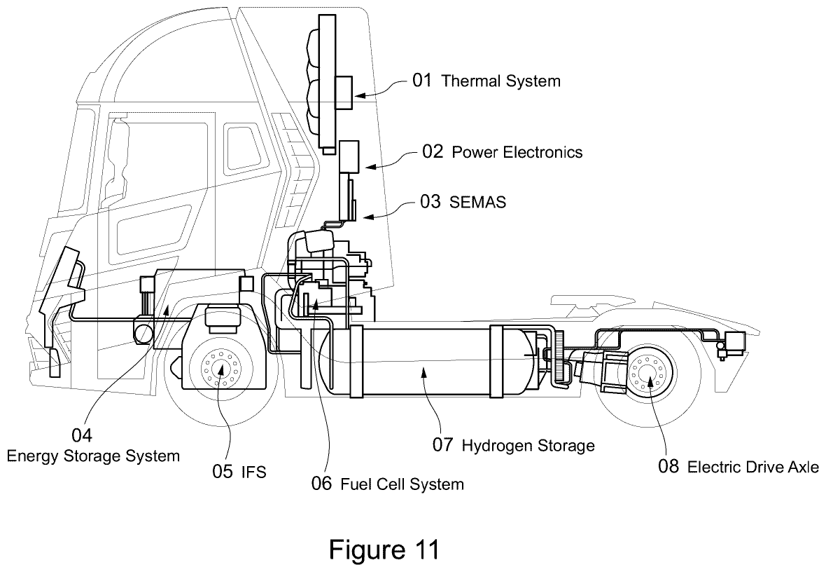

FIG. 11 is an example of an electric vehicle that utilises the control system of the present disclosure. In the example presented, the electric vehicle is a heavy goods vehicle. The powertrain of this vehicle includes both a fuel cell array 06 and an energy storage system 04.

The control system of the present disclosure addresses the challenges for fuel cell electric power trains where there is one or more fuel cell systems that provide the baseload power and there is also an energy storage system that provides supplementary power for peak power demand and as an energy store for regenerative braking. It also addresses the challenges of heavy goods vehicles where a highly variable power profile is dominated by the vehicle mass, which in turn is a function of vehicle load together with power demand for environmental controls, power take-off, cooling and other parasitics (non-motive power energy demands).

The control system uses large data sets of internal and external state variables, which are used in an active simulation of the operation of the electric vehicle, embodied in controller one. Controller one could be, for example, a SEMAS® artificial intelligence predictive drive (AIPD) controller. SEMAS® AIPD will analyse the proposed route, the amount of energy available from the hydrogen FC subsystem and the energy storage system and the predicted energy demand profile of the current route segment and remaining route. After this analysis, controller one will dynamically set the drive mode and the target state of charge at some time “t” corresponding to the end of one route segment and the beginning of another. The drive mode sets various Fuel Cell operating parameters, ESS and mechanical drive parameters to tune the power train for the current segment.

The control system of the present disclosure provides several benefits. Firstly, it improves the dynamic performance of the vehicle. Dynamically setting the drive mode of the vehicle also allows for the opportunity to embody a much larger set of drive modes, providing more exact tuning of the power train system parameters and set points in the main vehicle and subsystem controllers. Secondly, the route-based AI predictive control is used to define state-of-charge set points for the ESS along the route thereby ensuring that the vehicle reaches its destination and has sufficient power for high power demanding manoeuvres, such as climbing steep gradients and has sufficient capacity for maximum power absorption into the ESS on descent or planned deacceleration events. Thirdly, it allows for enhanced durability of the electrochemical subsystems of the power train. Fuel cell systems and battery based electrical energy storage have different rates of micro-degradation depending on such factors as current operating level, amplitude and frequency of power cycling and rate of change of power output some of which are dependent on the past operational profile and some on environmental conditions. By matching performance to the demands of the terrain with current requests from the driver along with the impacts of environmental conditions, the SEMAS® AIPD controller can optimise the balance between such parameters as overall vehicle power requirements, fuel economy, regenerative energy capture, and power train component durability.

In the present disclosure, the SEMAS® AIPD acts as an advisory controller setting a series of predetermined drive modes to optimize electric vehicle performance efficiency for a given route, while enhancing durability of the power train subsystems. The drive modes tuning parameters are then coded into controller two. Controller two can be, for example, the main VCU. The SEMAS® AIPD controller also sets the target SOC for the ESS at time “t”. Environmental and other inputs also go into the SEMAS® AIPD and can be presented as simplified state information to the driver via the human machine interface (HMI).

The SEMAS® AIPD employs AI-enabled predictive drive to optimise the operation of the fuel cell and energy storage system (battery system) subsystems of the power train to calculate the required energy profile across successive route segments in the overall route for the vehicle.

To do this, the SEMAS® AIPD controller requires the current gross vehicle mass, this parameter in combination with data related to the current terrain gradient permits the calculation of the instantaneous power demand of the vehicle. These factors are key determinants of the energy required for the vehicle to complete a specific manoeuvre, for example, climbing a gradient at speed.

For the SEMAS® control strategy, the acceleration, vehicle pitch and vehicle yaw are measured directly with a 6-axis inertial navigation unit, whereby the gradient measurement is compensated for by acceleration of the vehicle. Using the appropriate on-board sensors and models it is then possible to work backwards to determine the vehicle mass as this is invariant between load changes. The vehicle mass can be calculated from the following equation:

$$m = \frac{Pr}{( gCrr + a + g sin ( θ ) ) \cdot v} \qquad Eq . 1$$

Where:

| | |
|---|---|
| Pr | Instantaneous power demand |
| g | Gravitational acceleration |
| Crr | Rolling resistance coefficient |
| a | Vehicle acceleration |
| θ | Gradient |
| v | Vehicle velocity |

Gross vehicle mass and gradient profile are some of the main parameters that determine the energy needed to complete a given route. While in passenger cars mass does vary with the number of occupants and load, for commercial vehicles, whose main purpose is to carry and deliver a cargo payload, mass varies dramatically with the cargo type, loading conditions and delivery schedule.

The main function of the power train is to turn energy contained in the fuel to motive power at the wheels. The energy required to complete a route depends on several factors including the gradients experienced along the route, the velocity profile adopted across those gradients, the rate of acceleration demanded by the driver or drive controller, aerodynamic wind, road, traffic conditions, and the vehicle mass.

For commercial vehicles, the different drive styles adopted by different drivers can have a large effect on the energy used to complete a given route. This is primarily resultant from the use of acceleration and braking during the journey. Heavy acceleration followed by heavy braking dissipates wasteful energy from the fuel to heat in the braking system. Good drivers will vary speed to work with the traffic and the route terrain to minimise peak acceleration requirements. This requires a degree of skill and goes beyond driving at a constant speed. In such times, the energy storage systems and prime mover, for example, a FC subsystem work together to meet power demands during acceleration events. In the case of most electric vehicles, power can be absorbed in downward descents by energy transfer to the on-board ESS of the power train. This means that, the velocity profile can be optimised to work with the gradient profile of the selected route and to set up the state-of-charge of the energy storage system to deliver a least cost solution for the chosen route.

An essential input parameter within the model embedded in the VCU controller is the current gross mass of the vehicle. This can be derived using the techniques already known in the art, such as load counting and calculation, onboard load cells or external weighbridge. However, in the present disclosure the VCU controller makes use of the modelling data from the SEMAS® AIPD in combination with the rich data sets available from a modern electrified power train, such as a combination of a FC and ESS subsystem. The VCU controller uses the model and data sets to directly measure the mass of the vehicle using Equation 1, the changes in mass as the vehicle progresses along the route (such as taking on or dropping off cargo payloads), and to measure and confirm other parameters affecting the dynamics model (such as rolling resistance or drag factor).

The example embodiment of the VCU controller of the present disclosure can adjust set points of the energy storage system and FC subsystem in advance of demand to minimise the overall fuel consumption for a journey. It also can set up the vehicle for minimum energy consumption for a specific manoeuvre by, for example, driving along an extended upwards or downwards gradient. The VCU controller can further adjust the mass parameter of the model along the route to account for changes in the payload. It can provide for additional diagnostics if needed, such as rolling resistance or if the vehicle drag is out of the expected range (for example if the pressure in the tyres is too low).

The SEMAS® AIPD controller and the whole vehicle model it produces is intended to be a high-fidelity digital twin of power train functionality for an electric vehicle. It comprises three elements:

| | |
|---|---|
| SEMAS ® | Software tools to develop, test and maintain a high-fidelity |
| Modelling | dynamic model of the vehicle and its control system. |
| Suite | Comprises a whole vehicle model implemented, for |
| | example, in Simulink which includes software modules |
| | representing (at high fidelity) accurate physics-based |
| | models of the power train components, (in effect |
| | producing a digital twin of the vehicle power train). |
| | This includes a standard 1D Newtonian dynamics model of |
| | the vehicle and a suite of tools to run the model through |
| | standard drive cycles, and data sets representing real |
| | world terrain and end-user drive cycles, cargo management |
| | requirements, fleet management and driver safety/comfort. |
| | The suite aims to provide accurate geolocated datasets and |
| | contains software tools to generate synthetic terrains, |
| | real world terrains, representative of end user |
| | requirements, together with a suite of standard idealised |
| | drive cycles, to generate standardised performance data for |
| | any modular power train vehicle configurations. |
| SEMAS ® | The high-level supervisory intelligent controller that |
| AIPD | monitors vehicle states and provides these to the embed |
| Controller | digital twin within the controller to provide the |
| | intelligent control functions. |
| SEMAS ® | The functionality is provided with the vehicle and includes |
| Cloud | an on-board data logger, GPS, mapping, and satnav |
| | functionality together with 4G/5G connectivity that |
| | connects the SEMAS ® controller to the SEMAS ® Cloud. |
| | This will send high spatial resolution data on the vehicle |
| | subsystems status to the Cloud and receives processed data |
| | back to set-up the embedded controller of each segment of |
| | the route and provide condition monitoring and other fleet |
| | management services (described below). Other potentially |
| | useful telematics related to cargo management and total |
| | vehicle mass that provides addition data to further |
| | optimize vehicle energy management during the journey. |
| | The Cloud ultimately will also hold libraries of route |
| | segments that include vehicle subsystem performance data |
| | at high spatial resolution. |

The control system of the present disclosure addresses three fundamental challenges in electric vehicle power train design and operation. These are: vehicle dynamic performance, including cargo management and driver safety/comfort; fuel efficiency; and durability of the FC and ESS subsystems.

The power train in an electric heavy goods vehicle (HGV) comprises a lead/follower electric set-up with a Fuel Cell System, battery or other Energy Storage Systems (ESS), PEMD (power electronics, electric motor, and mechanical drive). The technology for the various subsystems in the electric vehicle power train are relatively immature, and the market does not yet offer a full range of specifications for all possible applications of the subsystems particularly for application in HGVs. Power train subsystem selection is limited to what is available. Moreover, some technology subsystems are on long lead-times from suppliers, and many are under development and or not yet fully field proven. This presents some problems providing a power train that meets expectations for load carry capacity, speed, range, and gradient performance under load as designs of vehicles are based on what subsystems are available, leading to compromises and trade-offs. The SEMAS® AIPD controller and the system modelling therein is based on generating a high-fidelity digital twin vehicle able to specify in advance the performance expectations for a specific configurations and specific use case. In addition, the SEMAS® AIPD controller allows for continuous improvement in vehicle operational characteristics and optimized durability of the power train subsystems.

Within the electric vehicle power train, there is most often an interaction of at least three energy sources to provide the motive power for the vehicle. These energy sources are comprised of; hydrogen which is the primary fuel, to be converted to heat and electrical power by the one or more fuel cell systems; electricity as stored in the energy storage system which may include one or more battery types or supercapacitor combinations; and potential/kinetic energy from the motion and elevation of the vehicle mass. There is also considerable waste thermal energy that arises from the FC, ESS and PEMD. Energy flows from these sources to meet the power demand of the vehicle. For electric HGVs, the primary energy source for the route is provided by the hydrogen stored on board and converted to electrical power in the FC system, while the ESS employed to meet the demands of power transients, providing peak power for hill climbing and acceleration and absorbing potential kinetic energy from braking during deceleration and hill descents. For electric HGVs with high masses, the ESS/vehicle dynamic interaction generates high energy flows. ESS stores energy and once at capacity it is no longer able to absorb energy from braking and this energy is potentially lost. When the ESS is depleted, it is no longer able to support the fuel cell subsystems to meet high transient power demands. It is in such scenarios as the optimization of the energy demand/supply that define, in part, the value and functionality of the SEMAS® AIPD controller.

The SEMAS® AIPD controller controls the set-up of the power train subsystems, for example, the ESS state of charge needed to anticipate upcoming transients in power demand and recapture such as acceleration, deceleration, and gradient terrain response. To do this, the SEMAS® AIPD controller needs to know the drive profile, and the gradients in the route ahead to predict the energy demand profile, along the various segments in the route, and the related power demand and thermal management requirements from the power train subsystems. Primary energy efficiency (the fuel efficiency) depends on maximising the use of the ESS to capture as much kinetic and potential energy as possible rather than dispersing this as heat in the mechanical brakes. In addition, the efficiency of the electrochemical subsystems (FC and ESS) falls off at high power demand, when these subsystems fall below their power output efficiency peaks. Both power train subsystems have efficiency curves that vary with power output, the secondary task of the SEMAS® AIPD controller is to adjust the energy balance between the energy sources to keep the subsystems as close to their optimum efficiency ranges as possible. The SEMAS® AIPD controller must also be sensitive to the changes in power output efficiencies of the powertrain subsystems as a function of such parameters as “aging”, ambient temperature, and altitude. For twin FC subsystems with minimum outputs on each, there are then two possible ways to generate a specific output: parallel drive or a lead/follower configuration which has already been described in detail in the present disclosure. Similarly, there are different configurations of the ESS, specifically as regards the capture of energy trough such processes as regenerative braking of the vehicle, most especially electric HGVs. For the SEMAS® AIPD controller, the opportunity for demand side response (DSR) to be incorporated as part of the energy balance is considered. DSR is where, rather than instantaneously increasing supply to meet the requested power demand, the demand is reduced (or delayed) to meet power supply constraints. This is particularly advantageous when to fully meet the short-term transients would lead to degradation of, and/or irreversible damage to the FC and/or ESS subsystems. Especially in scenarios where the power demand can be modulated for short periods of time with little effect on the overall vehicle performance.

In general, electrochemical devices do not response well to repeated high power transient events. It is well known that battery systems (based on existing chemistries) suffer enhanced degradation rates under repeated high power transient charge/discharge cycles. It is equally well documented that FC subsystems operated under a constant power demand scenario have enhanced durability over the same systems operated under dynamic power demand. The scale of these performance degradations depends on many factors including where in the electrochemical operating curve they occur (e.g., cycling at high states-of-charge is worse than when it occurs within the middle of the operating range of the ESS), as is the case with cycling at elevated or sub-zero temperatures, due to thermal effects. Both battery and FC subsystem (electrochemical devices) durability is life-limited by the dynamic operation that they experience. High power transients also lead to dynamic thermal stresses and as such are negative for the durability of these devices. Both types of devices suffer high “I” squared R losses at high power demand, so efficiency falls off at higher power outputs. Lower power level continuous operation is preferred for both the FC and ESS subsystems and will lead to longer life. As the FC subsystem is the currently the more expensive of the power train devices, on a $/kW basis, then protection of the FC subsystem over protection of the ESS is often the preferred strategy.

For batteries, as components of the ESS, the number of lifetime cycles is a fundamental limitation of these components of an ESS (true of all battery chemistries), this is seen as a lesser issue with supercapacitors. Battery life depends not just on the number of cycles but on the depth of discharge and the rate of charge/discharge. Such parameters are important in determining the optimum utility profile for the ESS. Therefore, by limiting the depth of discharge or maximum charge rate when full performance is not a key deliverable for a given segment, then enhanced life of these subsystems can be achieved. For example, one may need to limit the depth of discharge to achieve acceptable cycle life, this may be attained with sacrifice to the optimum capture the potential/kinetic energy during a braking event. A least cost algorithm can be used here to optimize the desired operational strategy. Energy efficiency is optimized when the ESS can also harvest and store all the available energy from vehicle slowing and braking events. As such, there is a dynamic “least cost” problem to be solved by the SEMAS® AIPD controller in balancing durability, performance, and energy efficiency constraints.

The overall control system of the present disclosure involves a split of control functions, such that the drive modes are embodied in the VCU controller. The VCU controller will be responsible for setting operational values of the FC(s), ESS, thermal management systems, and eAxle. Wherein the aAxle is an integrated Power electronics and Mechanical drive (PEMD) and in general comprises the electric motor or motors drive, a mechanical gearbox and means to deliver mechanical power to the vehicle wheels. The eAxle will usually include the inverter system and its own controller that co-ordinates the power electronic, inverters configuration and mechanical gear selection.

The drive modes are designed to produce gradations in vehicle power train operation by trading off optimum overall vehicle performance for enhanced fuel efficiency and durability. Therefore the VCU will include limits on such parameters on torque and peak power, hard and soft limits on ramp rates on ESS and FC subsystems and provide for limits on ESS power and charge rates and max/min SOC (and any other parameters that are discovered in testing such as setpoint on eAxle gear change, or any points on the operating curve of the FC and ESS subsystems that need to be avoided, or even the switch form parallel to a sequencing arrangement of power demand from the FC subsystem). By having a set of parameters for the desired energy management for the electric vehicle, for a given route, and simply switching between power demand contributions from the FC and ESS subsystems, the VCU controller can be tested, and the functional safety of these settings proven out. The VCU will then also take control of kick-down (or any emergency action states needed, for example related to safe operation of the vehicle which may require disengagement of a specific drive mode).

The SEMAS® AIPD controller undertakes the macro control functions for the journey including: terrain mapping, route segmentation, deriving the recommended drive mode, setting the target SOC of the ESS for the segment end, which involves determination of the drive mode for the next segment and evaluation of the energy and power demands for the next segment.

In FIG. 1, other functions for the SEMAS® AIPD control module are shown these include: hydrogen metrology; current load; remaining range and predicted fuel margin at destination; route energy demand graphic; and drive mode graphics.

For the hydrogen metrology function, the SEMAS® AIPD controller will make best estimate of the hydrogen remaining (the hydrogen fuel gauge). This will be a cross correlated measure of cylinder pressure and temperature of the fuel in the tanks (hydrogen fill state-hydrogen used as calculated, for example, from the FC efficiency map). Precise measurement of available hydrogen is essential to get a precise measure on available range, based on the calculated energy demand for the remaining journey. The effective hydrogen remaining in the vehicle on-board storage system can be calculated based on the initial hydrogen content determined from refuelling data, minus the amount of hydrogen consumed based on measurements, such as, product water produced from operation of the FC subsystem, after refuelling, cross-correlated with the calculation of the thermal rejection quantum from the FC system operation during the same operational time interval.

The dynamic simulation model of the SEMAS® AIPD controller requires the total vehicle mass as an input. While the vehicle tractor weight is known, the trailer tare and cargo payload are not. Rather than have this as a driver input, (subject to error), it is proposed that effective mass will be calculated by controller one 110 as the vehicle accelerates. The acceleration can be derived from the vehicle velocity signal and the onboard 3-axis accelerometer, while the energy delivered to the wheels will be calculated from the current and voltage to the eAxle, taking into account the efficiency map of the eAxle. Multiple estimates can be made with noise in the sensors eliminated to calculate the mass to a high level of precision using equation 1.

The remaining range and predicted fuel margin at destination will be fed to the HMI. The target objective for this metric, the effective mass of the vehicle, is estimated to be achieve with an accuracy of +/−3%, or better. This means that both the available hydrogen remaining and the estimated energy to complete the route will be required to possess a greater level of accuracy. Of course, major changes in route or in vehicle speed will cause the range calculation to fluctuate, but in normal motorway operation, with predictable average speed, then the range parameter should be sufficiently accurate.

The data for the route energy demand graphic will come from the route segmentation and remaining route module. This is a simple graphic showing the projected energy demand as a function of the journey and is purely indicative. The route energy demand graphic is intended to prepare the driver for the event that the vehicle performance might be somewhat compromised based on high energy demand manoeuvres. Ideally, this will be a rare occurrence only seen on high gradients of long duration and under high vehicle cargo loads when the energy capacity of the ESS may be a limiting factor.

The drive mode graphic (HMI) can be a relatively simply bar graph or dial-indicating fuel economy.

The SEMAS® AIPD controller is a whole system integration approach to energy management that considers energy flows at the whole system level. The whole system is defined as a system comprising the vehicle and its subsystems, including the driver, the cargo load, the route and terrain and the surrounding traffic and environmental conditions. It will be appreciated that the energy demand to perform a specific manoeuvre is a function of variables, such as, the target drive cycle, and dynamic factors such as cargo load, acceleration profile and terrain, with the environmental conditions and surrounding traffic flow introducing further secondary variables. In an electric vehicle the energy demand also includes the parasitic loads of such components as the thermal systems, lighting, additional system parasitic power demands, other environmentally determined characteristics, and other factors.

The control system of the present disclosure examines the predicted energy demand profile and controls the vehicle subsystems to meet that energy demand according to preset criteria. With the proposed split in functions between the SEMAS® AIPD controller and VCU controller, the preset criteria are embodied in the VCU controller while the selection of which set of preset criteria is appropriate for the current route segment is determined by the SEMAS® AIPD controller. These criteria will include both hard and soft constraints of the control system. An example of the preset criteria is the limitation on the peak power and the torque available to the driver at any point in time, for example, by constraining the FC/ESS combination to a specific peak power output. The VCU controller will then set the drive mode most compatible with these constraints. However, if the driver intervenes and demands more power than that predicted by the SEMAS® AIPD controller, then the VCU controller will determine which of the constraints is hard and which is soft. For example, the current maximum power change rate on the fuel cell may be a hard constraint, and the current peak power output of the ESS may be a soft constraint. The unmet peak power demand may also be a soft constraint. Therefore, the VCU controller will respond by taking the FC to the highest power change rate permitted under the given drive mode and will take the ESS system through the current max power limit to the next drive mode step and restricting power delivery to allow an unmet need for a short period until the FC power ramps up to the next level required. The VCU controller will also contain the functionality to attempt to drive the FC subsystem to meet the target SOC on the ESS, at a specified time. The estimate of the target objectives in a temporal domain is provided by the SEMAS® AIPD controller, which is determines this parameter from the vehicle speed and the assessment of the peak power demand and overall energy demand for the current and the next route segments.

Within the SEMAS® AIPD controller, several different time horizons are considered. Each time horizon will have a defined energy limitation. In the embodiment of the present disclosure there are, for the most part, three specific time horizons. The first is the RR, or more precisely, the RR to the next refilling stop. At the commencement of the planned route, the RR will be the whole journey. Clearly the primary limitation is the inventory of useable hydrogen stored on the vehicle. For an electric truck, the available energy content of the fuel, will be the total energy available to propel the vehicle and its cargo while managing all the parasitic loads, with a relatively small additional amount of energy stored in the ESS. This available energy needs to be higher than the planned energy consumption for route when taking into account such factors as the drive profile, terrain, vehicle load, environmental conditions (which will account for parasitic loads for running such functions as the vehicle cab AC, the fan loads from the thermal system and any thermal management requirements related to cargo health), all of which are journey specific parameters necessary to calculate the predicted energy demand for the remaining route. The SEMAS® AIPD controller will access these data from the vehicle Controller Area Network bus (referred to as the CANBUS). The second time horizon is the Current Journey segment. Within the SEMAS® AIPD controller modules the journey is split into segments. These segments are determined by the drive profile and the terrain profile of each segment. Within the route segment there will be a set energy budget which will take account of the total vehicle energy demand to undertake that segment. Once this energy budget is calculated then how this energy is to be supplied is determined by the SEMAS® AIPD setting a target drive mode and sending this information to the VCU controller. The FC subsystem energy budget will not only depend on the overall energy needed for this route segment but will take account of the start of segment and end of segment targets for the ESS SOC. The target SOC for the ESS end of segment is determined from the required SOC/energy budget for the following segment. The energy output of the FC subsystem may then be limited by ramp rate considerations to be something less than the highest peak output possible. To work within the energy budget then the available power at any point in time may be limited with a consequential effect of not meeting the demanded drive profile. The third time horizon is energy balance, which is the short-term energy balance. Given the proposed configuration for the control systems of the present disclosure, this is simply set by selecting one of the predetermined drive modes. Over the timeline of the defined route segment, the energy supply side must meet the energy demand. How this is handled within the VCU controller is to match supply and demand, either by increasing/decreasing energy supply (ramping up or down the FC subsystem power out) or increasing/decreasing energy demand by adjusting the energy rate characteristics of the eAxle, inverter, and the ESS. Instantaneous energy balance in the whole vehicle development model will be on a least cost basis, where the cost functions are embedded within the control systems. The cost functions will include such factors as the efficiency of each power train subsystem at its current operating point, the implications of transient and cycle requirements on the durability and reliability of the power train subsystems and the required target state or setpoint for the forthcoming vehicle manoeuvre during a given route segment. Lowest cost considers optimisation based on monitoring, analysing, and adjusting both the supply side and demand side of the total energy management for the whole vehicle. For an electric HGV with an energy storage system, it is possible to decouple and control transients in energy demand from variation in energy supply requirements. This capability is essential in achieving optimum efficiency and durability, and hence, the lowest TCO for electric vehicles, especially commercial electric vehicles. However, once this is achieved then these criteria and drive mode setting can be coded within the VCU as fixed parameter sets. These will include limitations on transient performance of FC and ESS subsystems. This will require a second module in the whole vehicle control system that models the VCU drive settings, after these have been determined by the least cost algorithms as developed and described above.

The target SOC of the ESS at a specific time, “t”, can be determined by the availability of capacity to store energy derived from regenerative braking systems and other energy recapture systems. It can also be determined based on the requirement of the ESS to assist the FC subsystem in providing power during acceleration and up-gradients. Calculation of the regenerative potential in the current and following segment of the vehicle journey will then determine the target SOC for the start and end of segment. For electric vehicle power trains, the primary energy generator for the whole route is the FC subsystem which converts on board hydrogen into electricity, water and heat. However, for a specific manoeuvre or route segment, the total energy available is provided by a combination of the fuel cell output, the energy stored in the electrical storage system (ESS), the stored mechanical energy in momentum and the gravitational energy available over that route segment. Gravitational energy arises from the vehicle mass and may be positive or negative depending on the gradient pertaining to that route segment. The stored mechanical energy may be harvested in some form of regenerative braking to provide energy to the ESS.

Each component of the energy store system will have both hard and soft limits on the available energy; namely the power and the rate at which power levels can be changed. For example, the absolute peak discharge rate will be a hard limit based on the manufacturers specification. Each drive mode will then have a peak discharge rate for that mode which can be interpreted as a soft constraint. The control systems will try to adhere to the soft constraints, but these can be overridden, as needed, by an unexpected transient in the power demand. These rate limitations may not be symmetrical, for example, the rate of charge or discharge on an ESS will be different relative to the acceptable rate of change of a FC subsystem output depending on whether the vehicle is experiencing an up transient or down transient in power demand. The amplitude and rate of power demand may also have limitations depending on the current operating point and additional parameters such as the state of the FC humidifier, the thermal management system, and the current environmental conditions. These energy outputs are then available to drive the vehicle through the power electronics, and motor drive (PEMD). The available energy demand will also include the required energy for vehicle peripherals (e.g., cab and cargo environmental energy requirements). The whole energy system allows for demand side management, for example, to achieve vehicle range or instantaneous power to complete a manoeuvre, it may be advantageous, for example, to interrupt cargo cooling for a short period to feed propulsion energy, without detriment to the viability of the cargo.

A skilled person will therefore appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. A control system for an electric vehicle comprising a power train, the control system comprising:
a first controller configured to automatically select a drive mode for the vehicle based on a whole vehicle operation model; and
a second controller coupled to the first controller, the second controller configured to adjust a set of tuning parameters for the vehicle,
whereby the second controller is configured to receive a signal from the first controller to adjust the set of tuning parameters such that the vehicle operates in the selected drive mode.

2. The control system of claim 1, wherein the first controller comprises a simulation module configured to provide the whole vehicle route model, the simulation module automatically selecting the drive mode for the vehicle.

3. The control system of claim 2, wherein the simulation module is configured to model one or more of the following in the generation of the whole vehicle model: thermal management of the powertrain; one or more hydrogen powered fuel cells with controlling balance-of-plant components; an energy storage system (ESS) comprising a battery, fuel cell and ESS thermal management; ESS state of charge data as it relates to optimized energy capture from regenerative braking; a high voltage DC/DC convertor; a HVAC subsystem; a power distribution subsystem; the second controller; a high voltage battery; an E-drive subsystem; a DC/AC inverter; an e-acle; a hydrogen fuel subsystem; one or more hydrogen tanks; a hydrogen supply and safety monitoring system; hydrogen capacity and refuelling capabilities; a parasitic loads management subsystem; a cabin environmental control subsystem; a cargo environmental and on-loading and off-loading control subsystem; an e-stop; a low voltage battery; and an axle-wheel-tyre subsystem.

4. The control system of claim 2, wherein the simulation module is configured to provide AI-enabled predictive control.

5. The control system of claim 1, wherein the first controller comprises one or more interfaces configured to receive a plurality of inputs, the whole vehicle model being dependent on these inputs.

6. The control system of claim 5, wherein at least one of the one or more interfaces is a wire communications interface.

7. The control system of claim 5, wherein the plurality of inputs comprises one or more types of input data from: a driver of the vehicle; route data; traffic data; environmental data; traffic management data; Global Positioning System data; terrain data; powertrain subsystem thermal management data; status of ES component data; parasitic load data; power flows in one or more subsystems of the vehicle data; DC/DC convertors and two way DC/AC inverter data for one or more power axles of the vehicle; vehicle speed and driver demand for change in speed data; acceleration and deceleration related to up- and down-gradients in journey terrain data; current hydrogen inventory data; ESS state of charge data; ESS state of charge data as it relates to optimized energy capture from regenerative braking; power demand ramp rate on fuel cell data or related water management data.

8. The control system of claim 1, wherein the AI-predictive control is configured to utilise remaining route data analysis to achieve specific drive mode operations that optimize fuel efficiency.

9. The control system of claim 1, wherein the AI-predictive control is configured to optimize energy management of the vehicle based on route segmentation analysis for a given journey.

10. The control system of claim 1, wherein the AI-predictive control is adapted to configure the ESS state-of-charge to provide optimum energy availability to support up-gradient acceleration of the vehicle, and down-grade energy recapture from regenerative braking.

11. The control system of claim 1, wherein the second controller comprises a vehicle control unit.

12. The control system of claim 8, wherein the vehicle control unit is configured to control the powertrain of the vehicle.

13. The control system of claim 11, wherein the vehicle control unit comprises at least one or more interfaces configured to adjust the set of tuning parameters.

14. The control system of claim 11, wherein the set of tuning parameters comprises at least one or more of: a fuel cell peak power limit, a fuel cell Power up slew rate, a fuel cell power down slew rate, an ESS max State of Charge (SOC), an ESS Min SOC, a target SOC at time “t”, a fuel cell array target power.

15. The control system of claim 1, wherein the set of tuning parameters are optimized using AI algorithms to achieve enhanced performance and durability of the vehicle power train subsystems.

16. The control system of claim 1, wherein the second controller functionality is replaced in its entirety by the first controller.

17. The control system of claim 1, wherein the selected drive mode is one of a plurality of operating modes comprising a performance mode, a balanced mode, a life extension mode, a fuel efficiency mode, a dynamic range adjust mode, a range extend mode, and a driver assist mode.

18. A method of automatically selecting and setting a drive mode for one or more/a plurality of segments of a route for an electric vehicle using the control system of claim 1.

19. The method of claim 18, wherein the electric vehicle comprises the control system of any preceding claim.

20. The method of claim 19, wherein the electric vehicle further comprises a plurality of energy sources and an energy storage means, wherein the plurality of energy sources comprises a one or more fuel cell subsystem.

21. The method of claim 20, wherein the plurality of energy sources comprises an energy storage system comprising a battery.

22. The method of claim 20, wherein the fuel cell subsystem comprises a hydrogen fuel cell.

23. The method of claim 20, wherein the fuel cell subsystem comprises an alternative electrochemical technology.

24. The method of claim 17, wherein the fuel cell subsystem comprises a proton exchange membrane fuel cell.

25. The method of claim 20, wherein the energy storage system is a battery.

26. The method of claim 17, wherein the energy storage system comprises a battery and a supercapacitor.

27. The method of claim 18, wherein the electric vehicle is a zero-emission commercial vehicle, powered by an electric powertrain comprising a fuel cell.
